(19) United States
(12) Patent Application Publication
(10) Pub. No.: US 2026/0162946 A1
(43) Pub. Date: Jun. 11, 2026

(54) PLASMA PROCESSING APPARATUS AND PLASMA PROCESSING METHOD

(71) Applicant: Hitachi High-Tech Corporation, Minato-ku, Tokyo (JP)

(72) Inventors: Tetsuo KAWANABE, Tokyo (JP); Makoto SATAKE, Tokyo (JP)

(21) Appl. No.: 18/690,918

(22) PCT Filed: May 25, 2023
(86) PCT No.: PCT/JP2023/019414

§ 371 Date: Mar. 11, 2024

(51) Int. Cl. H01J 37/32; H10P 72/00

(52) U.S. Cl. CPC H01J 37/32669; H01J 2237/334; H10P 72/0421

(57) ABSTRACT

In the present disclosure, in a plasma processing apparatus using ECR, information including parameters of a position and a shape of an ECR surface is used as an input value to a control device of the plasma processing apparatus. The ECR surface information that can be input to the control device from an input device of the plasma processing apparatus is limited by a discharge stability reference that is determined separately. When the discharge stability reference is satisfied, a plurality of coil current value candidates are extracted from a database including a correlation between a plurality of coil current values and the ECR surface shape information, and the plurality of coil current values to be input to a plurality of coils are determined from the plurality of coil current value candidates according to a coil current selection reference.

### TECHNICAL FIELD

The present disclosure relates to a plasma processing apparatus and a plasma processing method, and relates to a plasma processing apparatus that processes, such as etches, a substrate-shaped sample such as a semiconductor wafer disposed in a processing chamber in a vacuum container by using plasma formed in the processing chamber.

### BACKGROUND ART

A structure of a semiconductor device is becoming increasingly finer and more complex to achieve both improved calculation capability and lower power consumption. As complex manufacturing processes and highly difficult processing are required, the manufacturing cost of the semiconductor device increases. To reduce the manufacturing cost, it is effective to increase the number of high-quality semiconductor devices manufactured from one wafer, and it is necessary to obtain excellent process uniformity in a wafer plane.

In semiconductor device manufacturing, plasma processing such as plasma etching, plasma chemical vapor deposition (CVD), and plasma ashing is widely used. In an electron cyclotron resonance (ECR) method that is one method for generating plasma, the high-density plasma is generated in an isomagnetic surface (hereinafter, an ECR surface) where ECR is generated. To obtain excellent process uniformity, a plasma generation position is controlled by adjusting a position or a shape of the ECR surface in a plasma processing apparatus using the ECR method.

### CITATION LIST

### Patent Literature

PTL 1: Japanese Patent No. 6850912

### SUMMARY OF INVENTION

### Technical Problem

To obtain an excellent processing shape and uniformity in etching processing, a user of an etching apparatus considers various input parameters such as a gas type, a gas flow rate, pressure, radio frequency power for plasma generation, and radio frequency power applied to a substrate in each step constituting the etching processing, and inputs the input parameters into a recipe. The etching apparatus performs the etching processing by adjusting various parameters of the etching apparatus based on input recipe information. In the etching apparatus using ECR plasma, to form the ECR surface which is a plasma generation region in a plasma processing chamber of the etching apparatus by b using a coil, it is necessary to set a current value of the coil as the input parameter. As an adjustment knob for obtaining an excellent processing shape and wafer in-plane uniformity, the etching apparatus is provided with a plurality of the coils, and the plasma generation position is adjusted by changing a combination of currents supplied to the respective coils.

When a plurality of coil currents are input, there are various combinations of the currents, and it is difficult for the apparatus user to recognize what ECR surface is formed based on only the input current value. Therefore, the position or the shape of the ECR surface may be unintentionally inappropriate due to an erroneous input of the current value. As an inappropriate example, for example, the ECR surface may come into contact with a part having low plasma resistance inside the plasma processing chamber. At this time, ion sputtering is promoted in a region at which the ECR surface and the surface of the part are in contact with each other, and the part may be worn to generate particles. Alternatively, when there is an ECR surface in a gap between parts constituting the etching apparatus, abnormal discharge may cur in the gap portion. In addition, when the position or the shape of the ECR surface is inappropriate, discharge of generated plasma may be unstable, and a problem may occur in reproducibility of processing.

To avoid these problems, a method of limiting the current value of the coil that can be input to the recipe is considered. However, when the current value of the coil is limited to a predetermined range, use of the ECR surface that originally has no operation problems may be limited. That is, as a result of excessively limiting the position or the shape of the ECR surface, processing accuracy and wafer in-plane processing uniformity may not be obtained. PTL 1 proposes a method of measuring a position of an ECR surface with a height monitor. However, in PTL 1, no sufficient study has been made to designate a shape of the ECR surface at the time of a recipe input.

### Solution to Problem

In the present disclosure, in a plasma processing apparatus using ECR, information including parameters of a position and a shape of an ECR surface is used as an input value to a control device of the plasma processing apparatus. The ECR surface information that can be input to the control device from an input device of the plasma processing apparatus is limited by a discharge stability reference that is determined separately. When the discharge stability reference is satisfied, a plurality of coil current value candidates are extracted from a database including a correlation between a plurality of coil current values and the ECR surface shape information, and the plurality of coil current values to be input to a plurality of coils are determined from the plurality of coil current value candidates according to a coil current selection reference.

### Advantageous Effects of Invention

According to the present disclosure, the plasma processing apparatus can adjust the position and the shape of the ECR surface while avoiding use of the position and the shape of the ECR surface, which is prone to unstable discharge, part wear, and particle generation, and can implement plasma processing having excellent substrate processing accuracy and substrate in-plane uniformity.

### BRIEF DESCRIPTION OF DRAWINGS

FIG. 1 is a cross-sectional view of an etching apparatus according to a first example.

FIG. 2 is a flowchart according to the first example.

FIG. 3 shows a recipe input screen according to the first example.

FIG. 4 is an enlarged view of an ECR surface shape screen according to the first example.

FIG. 5 shows a database of coil currents and ECR surface shape information according to the first example.

FIG. 6 is a cross-sectional view of an etching apparatus according to a second example.

### DESCRIPTION OF EMBODIMENTS

Hereinafter, an embodiment and examples will be described with reference to the drawings. However, in the following description, the same components are denoted by the same reference numerals, and repeated description thereof may be omitted. The drawings may be shown more schematically than actual aspects to make the description clearer, but are merely examples and do not limit interpretation of the invention.

### Example 1

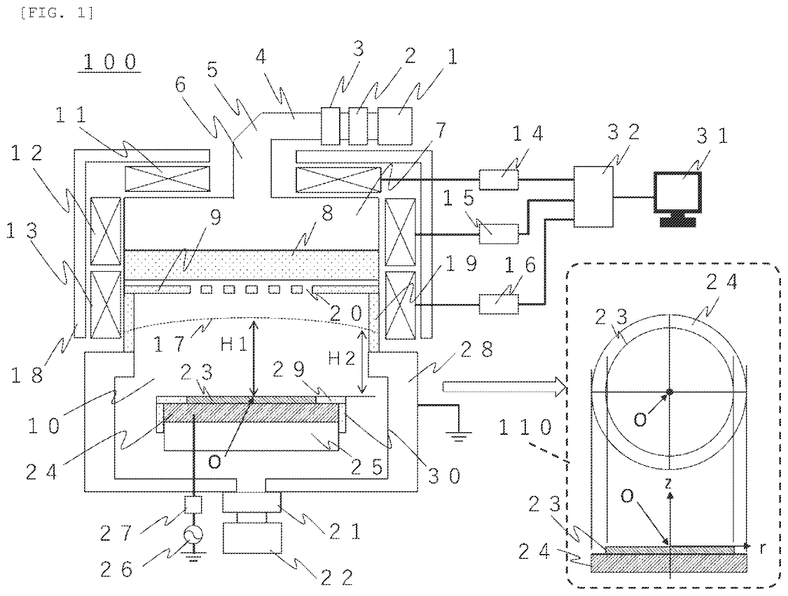

FIG. 1 is a cross-sectional view of an etching apparatus 100 according to a first example according to the present disclosure. The etching apparatus (also referred to as a plasma processing apparatus) 100 includes a configuration to be described below. Although the etching apparatus 100 will be described as a representative example in the following examples, the present disclosure is also applicable to the plasma processing apparatus. The etching apparatus 100 uses an electron cyclotron resonance (ECR) method that is one method for generating plasma, and the high-density plasma is generated in an isomagnetic surface (hereinafter, an ECR surface) where ECR is generated. To obtain excellent process uniformity, a generation position and a shape of the plasma are controlled by adjusting a position and a shape of the ECR surface in the plasma processing apparatus, which is the etching apparatus 100 using the ECR method.

Microwaves are oscillated from a microwave source 1 and transmitted from an isolator 2, an automatic matching device 3, and a rectangular waveguide 4 to a circular waveguide 6 via a circular rectangle converter 5. The microwave source 1 may be referred to as a unit that supplies radio frequency power of the microwaves for generating the plasma, a radio frequency power supply, or a microwave supply device. In the etching apparatus 100 according to the present example, microwaves of 2.45 GHz that are widely used industrially are used. The isolator 2 is used to protect the microwave source 1 from reflected waves of the microwaves, and the automatic matching device 3 is used to adjust a load impedance, prevent the reflected waves, and efficiently supply the microwaves. To facilitate handling of a propagation phenomenon of the microwaves, dimensions of waveguide cross sections are defined such that only a TE10 mode as a fundamental mode propagates through the rectangular wavelength 4 and only TE11 mode as a fundamental mode propagates through the circular waveguide 6. The microwaves propagate into a hollow portion 7 and are introduced into the plasma processing chamber 10 through a microwave introduction window 8 and a shower plate 9. The hollow portion 7 uses a conductor as a material for reflecting the microwaves. As a material of the hollow portion 7, for example, aluminum is used. The plasma processing chamber 10 may be simply referred to as a processing chamber or a reaction chamber.

To form a magnetic field necessary for the ECR inside the plasma processing chamber 10, an upper portion coil 11, a middle portion coil 12, and a lower portion coil 13 are provided outside the plasma processing chamber 10 as a plurality of coils. An upper portion coil power supply 14, a middle portion coil power supply 15, and a lower portion coil power supply 16 are connected to the coils 11, 12, and 13, respectively. The upper portion coil power supply 14, the middle portion coil power supply 15, and the lower portion coil power supply 16 are provided to supply currents (also referred to as coil currents) to the coils 11, 12, and 13, respectively. By adjusting a plurality of coil currents (also referred to as a plurality of coil current values) supplied to the coils 11, 12, and 13 by using the upper portion, middle portion, and lower portion coil power supplies 14 to 16, respectively, a position and a shape of an ECR surface 17 can be controlled. The ECR surface 17 may be referred to as an isomagnetic surface having a magnetic flux density for causing cyclotron resonance of charged particles by interaction with the microwaves in the processing chamber 10.

That is, the upper portion coil 11, the middle portion coil 12, and the lower portion coil 13 may be referred to as a first coil 11 constituting an upper stage electromagnet (first electromagnet), a second coil 12 constituting a middle stage electromagnet (second electromagnet), and a third coil 13 constituting a lower stage electromagnet (third electromagnet), respectively. The upper portion coil 11, the middle portion coil 12, and the lower portion coil 13 may be considered to be disposed coaxially (or axially symmetrically) with a central axis of the processing chamber 10 to surround the processing chamber 10. The central axis of the processing chamber 10 will be described later. In the present example, an example is described in which the coils 11, 12, and 13 are provided at three positions including an upper portion, a middle portion, and a lower portion, but the number of coils may be increased or decreased or positions of the coils may be changed as necessary to control the position and the shape of the ECR surface.

A yoke 18 has a role of preventing the magnetic field from leaking to an outside of the plasma processing chamber 10, and also has a role of adjusting a magnetic line shape inside the plasma processing chamber 10.

In the example, the upper portion coil 11 is provided to surround an upper portion outside the processing chamber 10 except for a disposition portion of the circular waveguide 6. The middle portion coil 12 is provided below the upper portion coil 11 and to surround periphery of an upper side surface portion outside the processing chamber 10. In the example, the middle portion coil 12 is provided around the outer upper side surface portion of the processing chamber 10 to surround outer periphery of the hollow portion 7 and the microwave introduction window 8. The lower portion coil 13 is provided below the middle portion coil 12 and to surround periphery of a side surface portion of an intermediate portion outside the processing chamber 10. In the example, the lower portion coil 13 is provided around the side surface portion of the intermediate portion outside the processing chamber 10 between a lower portion 44 the microwave introduction window 8 and a substrate stage and radio frequency electrode 24 to be described later.

To protect a sidewall of the plasma processing chamber 10 from the plasma, an inner cylinder 19 is provided inside the sidewall of the plasma processing chamber 10. The inner cylinder 19 located in the vicinity of the plasma uses quartz as a material having high plasma resistance. Alternatively, as a material having high plasma resistance, yttria, alumina, yttrium fluoride, aluminum fluoride, aluminum nitride, or the like may be used.

As materials of the microwave introduction window 8 and the shower plate 9, quartz is used as a material through which the microwaves are transmitted and a material that is transparent. Alternatively, as the materials of the microwave introduction window 8 and the shower plate 9, another dielectric material may be used as long as the material transmits the microwaves and is transparent.

A gas is supplied between the microwave introduction window 8 and the shower plate 9 from a gas supply unit (also referred to as a gas supply device) that is not shown. The gas supply unit has a function of supplying a desired flow rate by a mass flow controller. In addition, a gas type to be used is appropriately selected according to a processing target film, and a plurality of gas types are supplied in combination at a predetermined flow rate. A plurality of gas supply holes 20 are formed in the shower plate 9, and the gas is supplied to the plasma processing chamber 10 through the gas supply holes 20.

The supplied gas is evacuated by a turbo molecular pump 22 via a conductance adjustment valve 21. In a lower portion of the plasma processing chamber 10, the substrate stage and radio frequency electrode 24 on which a processing target substrate 23 is placed and an insulating plate 25 below the substrate stage and radio frequency electrode 24 are provided, and bias power is supplied to the substrate stage and radio frequency electrode 24 from a bias power supply 26 via an automatic matching device 27. To perform desired etching, energy of ions incident on the processing target substrate 23 is controlled by adjusting the bias power. Here, the processing target substrate 23 may be implemented, for example, such that a processing target structure is formed on a surface (also referred to as a plane) which is a main surface of a semiconductor wafer. In the description, the processing target substrate 23 may be simply referred to as a sample or a wafer. Further, the substrate stage and radio frequency electrode 24 may be simply referred to as a sample stage or a placement stage.

Further, a ground electrode 28 is provided at a lower portion of a plasma processing wall to provide ground (ground potential, ground reference potential) to radio frequency (RF) power supplied to the substrate stage and radio frequency electrode 24. The substrate stage and radio frequency electrode 24 is provided with an adsorption mechanism and a temperature adjustment unit (not shown) for the processing target substrate 23, and a temperature of the processing target substrate is regulated as necessary. To protect an outer peripheral portion of the substrate stage and radio frequency electrode 24 from the plasma, a susceptor 29 and a stage cover 30 are provided. The susceptor 29 and the stage cover 30 use quartz as a material having high plasma resistance. The etching is performed by generating the plasma by the ECR on the ECR surface 17 formed by the microwaves supplied from the microwave source 1 and the upper portion, middle portion, and lower portion coils 11, 12, and 13, and irradiating a surface (processing target surface) of the processing target substrate 23 with the generated ions and radicals.

To implement the desired etching, an apparatus user designates various input parameters in the etching apparatus 100. For example, parameters such as a gas type and pressure are adjusted according to a processing target film, a desired processing shape, or the like. The parameters are designated in a control computer (also referred to as a control device) 32 as a recipe in which the input parameters are collected through a graphical user interface 31 as an input device provided in the etching apparatus 100. In etching processing, control signals are output from the control computer 32 to various components in the etching apparatus 100 based on information on the recipe. For example, the control signals from the control computer 32 are output to the upper portion, middle portion, and lower portion coil power supplies 14 to 16, and currents designated by the recipe are output. That is, the control computer 32 is implemented to control the coil power supplies 14 to 16. Although not shown, the control signals are output to various components provided in each device such as the microwave source 1, the bias power supply 26, the conductance adjustment valve 21, and the mass flow controller, and the microwave power, the RF power, the pressure, the gas flow rate, and the like are controlled.

In a plasma generation method using the ECR, since the coils (11, 12, and 13) are used, it is necessary to designate the current values of the coils (11, 12, and 13) when the recipe is created. To designate the coil current values of the coils (11, 12, and 13), a result obtained by previously calculating shape information of the ECR surface 17 by an external computer is examined, and the coil current values are selected and input to the recipe. However, when inputting numerical values of the coil current values into the recipe, the apparatus user cannot recognize the shape of the ECR surface 17 only by the numerical values, and therefore the apparatus user may not be aware of an incorrect position or shape of the ECR surface 17 caused by an incorrect input. As an inappropriate case, for example, when the position of the ECR surface 17 is in a gap portion between parts, the parts may be worn due to abnormal discharge between the gap of the parts. In addition, when the position of the ECR surface 17 comes into contact with a part having low plasma resistance, the part is worn by sputtering on a surface of the part, and in some cases, particles are generated. Alternatively, when the ECR surface 17 is formed outside the plasma processing chamber 10, the plasma discharge itself is unstable, and it is difficult to implement stable etching. To avoid such a problem, a method of limiting the coil current values that can be input to prevent the originally unintended ECR surface 17 from occurring can be considered. There are various combinations of the coil current values of the upper portion, middle portion, and lower portion coils 11, 12, and 13, but when a limit is given to an input range of the coil current value, the number of combinations is greatly reduced, and ranges of the position and the shape of the controllable ECR surface 17 are limited more than necessary. That is, the processing accuracy and the wafer in-plane processing uniformity, which are originally possible when there is no limitation, cannot be obtained due to the limitation of the coil current.

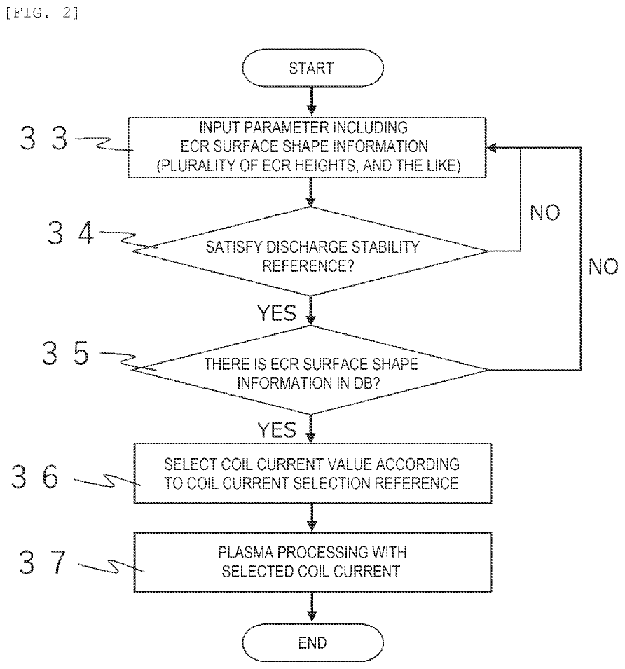

In consideration of these problems, a plasma processing method according to the present example was devised. The plasma processing method will be described with reference to a flowchart shown in FIG. 2.

First, in step 33, the user inputs a parameter of shape information (ECR surface shape information) of the ECR surface 17 to the control computer 32 via the graphical user interface 31. That is, in step 33, the control computer 32 receives, from the input device 31, information on a shape of the isomagnetic surface having a magnetic flux density for causing cyclotron resonance of the charged particles by interaction with the microwaves. Step 33 may be referred to as a step in which the information on the shape of the isomagnetic surface (ECR surface 17) input from the input device 31 is used as an input value of the control computer 32.

The shape information of the ECR surface 17 described here indicates information designating the position and the shape of the ECR surface 17. In the present example, since the magnetic field axially symmetrical with respect to the central axis of the plasma processing chamber 10 is formed by the coils 11, 12, and 13, the position and the shape of the ECR surface 17 may be considered on a two-dimensional plane in a radial direction and a height direction of the plasma processing chamber 10 of the etching apparatus 100.

As a method of designating the position and the shape of the ECR surface 17, a method of designating the position and the shape based on the height of the ECR surface 17 at a plurality of radial positions of the ECR surface 17 is considered. For example, as shown in FIG. 1, as the shape information of the ECR surface 17, a distance (hereinafter referred to as an ECR height) H1 in the height direction between a plane of a wafer 23 on the central axis of the apparatus (plasma processing chamber 10) and the ECR surface 17 and an ECR height H2 in an outer peripheral portion (outer peripheral portion of the inner wall of the plasma processing chamber 10: an inner wall of the inner cylinder 19 provided inside the side wall of the plasma processing chamber 10) of the apparatus (plasma processing chamber 10) may be designated. That is, the information (H1 and H2) on the shape of the ECR surface 17, which is the isomagnetic surface, includes distances (here, two heights: H1 and H2) in a vertical direction between the isomagnetic surface 17 at a plurality of positions in the radial direction and a plane of a surface of the wafer 23 when viewed from the central axis of the plasma processing chamber 10.

Alternatively, the shape information of the ECR surface 17 may be designated in another input format. For example, information on a curvature of the ECR surface 17, an inclination at a certain point on a curve of the ECR surface 17, an approximate curve of the ECR surface, or the like may be used. It is preferable that the number of parameters for designating the shape of the ECR surface 17 is not too much and is the minimum number required such that the apparatus user can easily create the recipe.

Here, the central axis of the plasma processing chamber 10, the radial direction and the height direction of the plasma processing chamber 10, and the like will be described with reference to FIG. 1. Inside a dotted line 110 in FIG. 1, a top view and a cross-sectional view of the substrate stage and radio frequency electrode 24 and the wafer 23 placed on a placement surface of the substrate stage and radio frequency electrode 24 in the plasma processing chamber 10 are drawn. As shown in the top view, when the wafer 23 is subjected to plasma processing, a central point O of the wafer 23 having a substantially circular shape is disposed inside the plasma processing chamber 10 to overlap a central point of the placement surface of the substrate stage and radio frequency electrode 24 and a central point of the plasma processing chamber 10. That is, the central point of the placement surface of the substrate stage and radio frequency electrode 24 and the central point of the plasma processing chamber 10 are disposed on the central axis of the plasma processing chamber 10, and the central point O of the wafer 23 is also disposed on the central axis of the plasma processing chamber 10. An axis passing through the central point O of the wafer 23 and perpendicular to the plane of the surface of the wafer 23 is indicated as a z axis. An axis in the radial direction that passes through the central point O of the wafer 23 and is parallel to the plane of the surface of the wafer 23 is indicated as an r axis. The z axis can be regarded as a central axis of the apparatus (plasma processing chamber 10). The radial direction and the height direction of the plasma processing chamber 10 correspond to an r axis direction (radial direction) and a z axis direction (vertical direction), respectively.

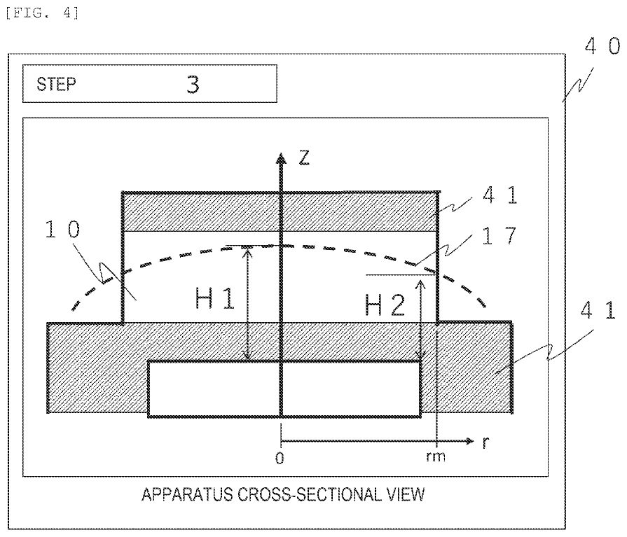

As shown in FIG. 1, the distance (hereinafter, ECR height) H1 in the height direction between the plane of the wafer 23 on the central axis of the apparatus (plasma processing chamber 10) and the ECR surface 17 is a height from the ECR surface 17 on the central point O of the wafer 23, a value of the z axis in the height direction is H1 (z=H1), and a value of the r axis in the radial direction is zero: 0 (r=0). Further, for the ECR height H2 in the outer peripheral portion of the apparatus (plasma processing chamber 10), a value of the z axis is H2 (z=H2), and a value of the r axis in the radial direction is, for example, rm (r=rm). rm is a distance between the central axis of the plasma processing chamber 10 (central point O of wafer 23) and the inner wall of the outer peripheral portion of the plasma processing chamber 10 in the top view (for example, see FIG. 4).

Next, in step 34, the control computer 32 determines whether the input parameter satisfies a discharge stability reference. The discharge stability reference is a reference for defining ranges of the position and the shape of the ECR surface 17 that can be stably used. The reference is created by using a result obtained by examining in advance stability of discharge, an amount of generated particles, and the like when the shape of the ECR surface 17 is changed. The stability of discharge can be examined by confirming a temporal change of the discharge by observation by a camera or measurement using a probe. For example, as a result of a preliminary evaluation of the discharge stability performed to create the discharge stability reference, when the ECR surface 17 approaches a lower surface of the shower plate 9, local discharge occurs in a central portion of the lower surface of the shower plate 9 (lower surface of the shower plate 9 on the z axis), and a problem in the plasma processing occurs. Based on the result, the discharge stability reference (first discharge stability reference) is defined as, for example, “the ECR heights H1 and H2 are defined to be lower by 30 mm or more than a distance between the processing target substrate 23 (the surface of the processing target substrate 23) and the shower plate 9 (the lower surface of the shower plate 9)” (that is, the ECR heights H1 and H2 are set to be lower by 30 mm or more than the lower surface of the shower plate 9). In addition, when the ECR surface 17 is formed in a gap portion between the inner cylinder 19 and the ground electrode 28, abnormal discharge may occur in the gap portion. Therefore, another discharge stability reference (second discharge stability reference), for example, is defined as “the ECR height H2 is set to be higher by 30 mm or more than a distance between the gap portion between the inner cylinder 19 and the ground electrode 28 and the processing target substrate 23 (the surface of the processing target substrate 23)” (that is, the ECR height H2 is set to be higher by 30 mm or more than the distance between the surface of the processing target substrate 23 and the gap portion between the inner cylinder 19 and the ground electrode 28). In addition, another one or a plurality of discharge stability references may be created based on the shape information of the ECR surface 17 in which a problem in the plasma processing occurs such as a condition in which a particle is likely to be generated or the discharge is unstable.

That is, an input range in the information on the shape of the isomagnetic surface (shape information of the ECR surface 17) input from the input device 31 is limited based on a predetermined reference (here, the first discharge stability reference and the second discharge stability reference). When the input parameter does not satisfy the discharge stability reference, re-input is prompted to set a condition satisfying the discharge stability reference (in a case of NO in step 34, the processing returns to step 33). As will be described later, since an input screen of the recipe is actually configured with providing a display area such that the shape information of the ECR surface that can be input is visually displayed on the input screen, it is possible to reduce the number of situations in which the re-input is required. When the discharge stability reference is satisfied (YES in step 34), the processing proceeds to step 35.

In step 35, the control computer 32 confirms whether the input shape information of the ECR surface 17 is present in a DB (database). The DB is stored in advance in a memory device of the control computer 32. The DB stores the coil current values of the coils 11, 12, and 13 and the shape information of the ECR surface 17 corresponding to the coil current values. That is, the DB stores information on a correlation between the coil current values of the coils 11, 12, and 13 and the ECR surface 17. When there is no coil current value corresponding to the input shape of the ECR surface 17 in the DB, the re-input is prompted to have an appropriate value (in a case of NO in step 35), and the processing returns to step 33. Since both of the shape information of the ECR surface 17 satisfying the discharge stability reference and the information on the correlation related to the coil currents of the coils 11, 12, and 13 are stored in the DB, the shape of the ECR surface 17 clearly deviating from the discharge stability reference is designated when the re-input is prompted. When there is an input shape of the ECR surface 17 in the DB (YES in step 35), the processing proceeds to the next step 36.

Here, in step 35, when there is an input shape of the ECR surface 17 in the DB, the reference for the determination by the control computer 32 is that a numerical value of the input shape information of the ECR surface 17 and a value of the DB do not necessarily have to completely match, and the input shape of the ECR surface 17 may be regarded as existing in the DB even when the numerical value of the input shape information of the ECR surface 17 and the value of the DB approximately match. For example, it is sufficient that there is data within a range of an allowable range ±ΔH with respect to input values of the ECR heights H1 and H2 in the DB. For example, 3 mm is used as ΔH. ΔH is determined based on accuracy of the shape of the ECR surface 17 required to implement the desired etching.

In addition, in step 35, when the number of parameters designated as the shape information of the ECR surface 17 is small, or when the above-described determination reference has a width, the coil current values of the coils 11, 12, and 13 for implementing the input shape of the ECR surface 17 are not necessarily uniquely determined, and there may be a plurality of coil current values. That is, step 35 may be referred to as a step of extracting a combination of a plurality of coil current values for implementing the shape of the isomagnetic surface 17 according to the information (H1 and H2) on the shape of the isomagnetic surface 17 from the database DB including a correlation between the plurality of coil current values supplied to the plurality of coils 11, 12, and 13 and the shape of the isomagnetic surface 17. Alternatively, step 35 may be referred to as a step in which the control computer 32 obtains a combination of the values of the currents supplied to the coils 11, 12, and 13 for forming the shape of the isomagnetic surface input from the input device 31 based on the correlation between the current values supplied to the coils 11, 12, and 13 and the shape of the isomagnetic surface.

In the next step 36, the control computer 32 uniquely selects or determines one value (one combination of the coil current values of the coils 11, 12, and 13) from a plurality of candidates of the coil current values of the coils 11, 12, and 13 obtained in step 35 according to a coil current selection reference. For example, as an example of the coil current selection reference, a coil current selection reference determined to minimize coil power consumption of the coils 11, 12, and 13 may be used among the plurality of candidates of the coil currents to uniquely select or determine a combination of the coil current values. Alternatively, as another coil current selection reference, a coil current selection reference determined such that a gradient of the magnetic flux density in the z direction is maximized (in other words, the gradient of the magnetic field on the central axis of the processing chamber 10 is maximized) on the ECR surface 17 on the central axis of the apparatus (plasma processing chamber 10) may be used to select or determine a combination of the coil current values. In addition to the coil current selection references described above, any determination reference that can uniquely determine each coil current of the coils 11, 12, and 13, such as “sort the current values of the upper portion coil 13 in an ascending order and adopt a condition at the top”, may be used. That is, step 36 may be referred to as a step of uniquely determining, according to the coil current selection reference, a plurality of coil current values in one desired combination for driving the plurality of coils 11 to 13 from combinations of coil current values for implementing the shape of the isomagnetic surface 17. Alternatively, step 36 may be referred to as a step in which the control computer 32 obtains, based on the coil current selection reference, one desired combination of current values from the combinations of current values obtained in step 35. The coil current selection reference is a reference created based on a current at which power consumption of the coil power supplies of the coils 11, 12, and 13 is minimized and the shape of the isomagnetic surface input from the input device 31. Alternatively, the coil current selection reference is a reference created based on a current at which the gradient of the magnetic field on the central axis of the processing chamber 10 is maximized and the shape of the isomagnetic surface input from the input device 31.

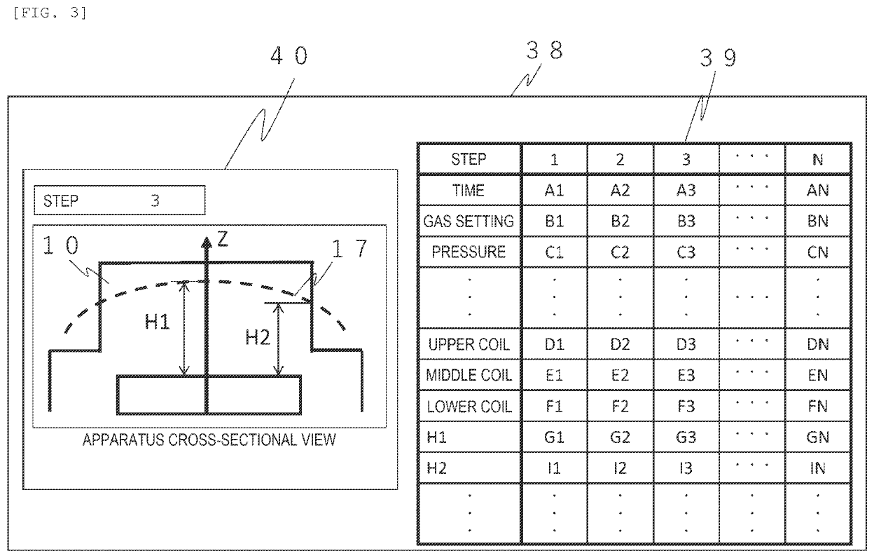

Finally, in step 37, the control computer 32 performs the plasma processing by using the coil currents of the coils 11, 12, and 13 selected in step 36. That is, the plurality of coil power supplies 14 to 16 are controlled to drive the plurality of coils (11 to 13) with a plurality of coil current values in one desired combination. In other words, the control computer 32 controls the coil power supplies 14 to 16 to cause the respective currents in the desired combination of the current values obtained in step 36 to flow. Then, the processing target substrate 23 is plasma-processed by the desired plasma generated in the processing chamber 10. Here, the plasma processing method shown in FIG. 3 can be summarized as follows. (Step 33): a step of inputting, from the input device 31 to the control computer 32, the information on the shape of the isomagnetic surface having the magnetic flux density for causing the cyclotron resonance of the charged particles by the interaction with the microwaves, (step 34): a step of determining, by the control computer 32, whether the information on the shape of the isomagnetic surface input from the input device 31 satisfies the discharge stability reference, (step 35): a step of obtaining, by the control computer 32, a combination of the current values of the coils (11, 12, and 13) for forming the shape of the isomagnetic surface input in step 33 based on a correlation (DB) between the current values of the coils (11, 12, and 13) and the shape of the isomagnetic surface, (step 36): a step of obtaining, by the control computer 32, one desired combination of the current values from the combinations of the current values of the coils (11, 12, and 13) obtained in step 35 based on the coil current selection reference, and (step 37): a step of controlling, by the control computer 32, the coil power supplies 14 to 16 to cause each current in the desired combination of the current values of the coils (11, 12, and 13) obtained in step 36 to flow.

When the apparatus user inputs the shape information of the ECR surface 17 satisfying the discharge stability reference into the recipe, the shape information of the ECR surface 17 is automatically converted into the coil current values of the coils 11, 12, and 13 according to the flowchart in FIG. 2. The control computer 32 controls the coil power supplies 14 to 16 to generate the coil current values of the coils 11, 12, and 13. The coils 11, 12, and 13 are driven by using the coil current values of the coils 11, 12, and 13 to generate the desired plasma in the plasma processing chamber 10. Accordingly, the surface (processing target surface) of the processing target substrate 23 placed on the substrate stage and radio frequency electrode 24 in the plasma processing chamber 10 is plasma-processed by using the desired plasma. Therefore, according to the etching apparatus 100 of the present example, it is possible to perform the plasma processing having excellent substrate processing accuracy substrate in-plane processing uniformity on the processing target substrate 23.

According to the present example, the apparatus user can search processing conditions under which the discharge is stable and the particle generation amount is small by a simple recipe input for a condition of the coil current values of the coils 11, 12, and 13 under which the processing accuracy and the processing uniformity of the etching can be obtained.

FIG. 3 shows a configuration example of a recipe input screen 38 according to the first example. The recipe input screen 38 includes a recipe 39 and an ECR surface shape screen 40. The recipe 39 is a table of the parameters input to the plasma processing apparatus 100, includes a plurality of steps, and includes items for inputting the parameters in each step. For example, there are setting items such as time, gas type, flow rate setting, and pressure of each step. The ECR heights H1 and H2 in the table correspond to the shape information of the ECR surface 17. An upper coil, a middle coil, and a lower coil represent setting currents (coil current values) of the upper portion coil 11, the middle portion coil 12, and the lower portion coil 13, respectively. As the coil current values of the coils 11, 12, and 13, a combination of the coil currents of the coils 11, 12, and 13 is determined based on the input information on the ECR heights H1 and H2 according to the flowchart in FIG. 2 and is automatically input into the recipe 39.

In the present example, the setting currents of the coils 11, 12, and 13 are displayed on the recipe input screen 38 for the sake of simplicity, but normally, the coil currents of the coils 11, 12, and 13 are not values to be input by the user, which are set to be hidden. Setting for displaying and hiding the coil current values of the coils 11, 12, and 13 can be selected at any time on a setting screen (not shown).

In the present example, the shape information of the ECR surface 17 is used as the parameter input to the recipe 39, but when the coil current values of the coils 11, 12, and 13 are desired to be used as a parameter to be input directly, the coil current values of the coils 11, 12, and 13 can be edited by setting direct editing of the coil currents of the coils 11, 12, and 13 on a setting screen (not shown). At this time, in contrast, since the ECR heights H1 and H2 in the recipe 39 are not parameters that can be edited by the user, the ECR heights H1 and H2 may be changed to a hiding setting.

When a cell is edited in the recipe 39, the shape of the ECR surface 17 in a step to which the cell belongs is output to the ECR surface shape screen 40. A cross-sectional view of the plasma processing chamber 10 and the ECR surface 17 are drawn on the ECR surface shape screen 40. The ECR surface 17 is the ECR surface 17 in which the coil current values of the coils 11, 12, and 13 are calculated according to the flowchart in FIG. 2 based on the information on the ECR heights H1 and H2 input to the recipe. Alternatively, when the coil current values of the coils 11, 12, and 13 are used as the input parameter, the ECR surface 17 at that time is displayed.

FIG. 4 is an enlarged view of the ECR surface shape screen 40 in FIG. 3. In FIG. 4, since the discharge stability reference is that “the ECR heights H1 and H2 are lower by 30 mm or more than the distance between the processing target substrate 23 and the shower plate 9” and “the ECR height H2 is higher by 30 mm or more than the distance between the gap portion between the inner cylinder 19 and the ground electrode 28 and the processing target substrate 23”, an unusable area of the ECR surface 17 is visualized as a forbidden area 41 of the ECR surface 17. The apparatus user can input the appropriate ECR surface 17 with reference to the forbidden area 41 of the ECR surface 17. That is, an erroneous input of the recipe and an inappropriate use of the ECR surface 17 are avoided. A screen layout of the recipe input screen 38 is not limited to that described in the present example as long as it has the same function as that described in the present example.

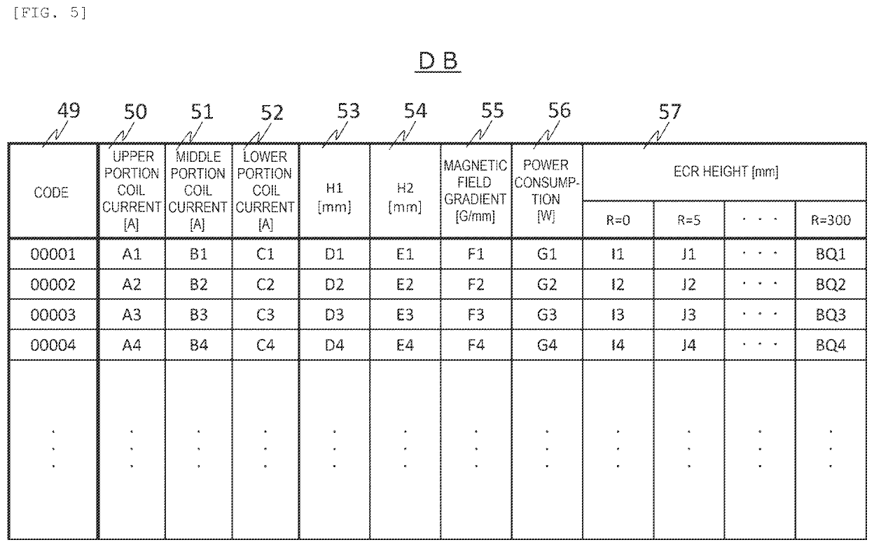

FIG. 5 shows a configuration example of the DB according to the present example. In the DB, information including a code 49, an upper portion coil current 50, a middle portion coil current 51, and a lower portion coil current 52 supplied to the upper portion coil 11, the middle portion coil 12, and the lower portion coil 13, the ECR heights H1 (53) and H2 (54) corresponding thereto, a magnetic field gradient 55 that is a gradient of the magnetic flux density in the z direction on the apparatus central axis (the central axis of the plasma processing chamber 10), power consumption 56 of the coil, and an ECR height 57 at each position in the radial direction, which correspond to code numbers described in the code 49, is described. In the DB, the currents 50, 51, and 52 of the upper portion, middle portion, and lower portion coils 11 to 13 are comprehensively described in a settable range. The DB is not limited to the above-described parameters, and may include parameters related to the shape information of the ECR surface 17, or may not include unnecessary parameters.

### Example 2

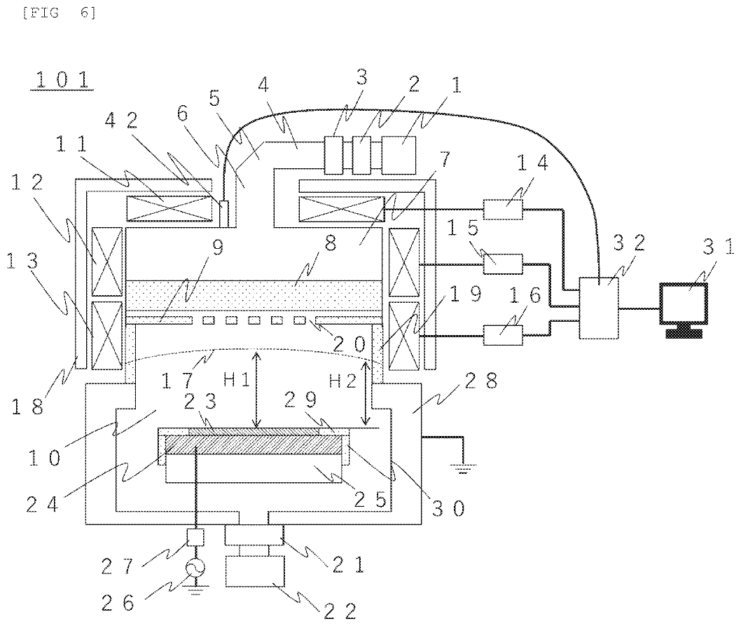

A plasma processing apparatus according to a second example will be described with reference to FIG. 6. In a plasma processing apparatus 101 similar to that shown in FIG. 1, a camera 42 for observing plasma in the plasma processing chamber 10 is newly connected above the hollow portion 7. Since the plasma processing apparatus 101 is the same as the plasma processing apparatus 100 described with reference to FIG. 1 except for the camera 42, redundant description will be omitted. The camera 42 may also be referred to as a measurement device that measures a position of an isomagnetic surface (ECR surface 17).

The camera 42 is used to confirm flickering of plasma discharge and determine processing conditions under which the discharge is unstable. For example, when a discharge stability reference is created, conditions of the ECR surface 17 under which the discharge is stable can be determined based on information from the camera 42. Non-invasive measurement using optical information from the camera 42 is desirable for measuring discharge instability to create the discharge stability reference, and an unstable discharge condition may be measured by an invasive unit such as a probe to create the discharge stability reference. In the first example, a case is described in which the discharge stability reference is defined based on the shape information of the ECR surface 17 and a positional correlation with the parts. However, since a condition under which the discharge is unstable is affected by parameters other than the positional relationship with the parts such as the pressure and the gas type supplied to the plasma processing apparatus 101, it is desirable to create the discharge stability reference by examining a correlation between the parameters and the shape of the ECR surface 17. That is, the reference may be created such that the shape of the ECR surface 17 that can be input and determined by the discharge stability reference changes according to the parameters such as the pressure and the gas type. However, since the number of parameters that can be designated by the recipe is enormous, it is not realistic to create the discharge stability reference by examining the discharge stability for all combinations. For example, by acquiring the discharge stability of the processing condition by the camera 42 as training data and performing machine learning and regression analysis, a model for predicting what recipe results in unstable discharge may be created, and the discharge stability reference may be created based on the model.

A position of the ECR surface 17 can be estimated by observing an area having strong light emission by the camera 42. The position of the ECR surface 17 may deviate from a position assumed in calculation due to factors such as a variation in magnetic characteristics of the yoke 18, an error in apparatus assembling, and an error in output current values of the coil power supplies 14, 15, and 16. When the position and the shape of the ECR surface 17 measured by the camera 42 are deviated from the position and the shape of the ECR surface 17 that should be implemented by calculation, a deviation amount is fed back to the control computer 32. The control computer 32 performs correction on the coil currents of the coils 11 to 13 such that the measured position and the measured shape of the ECR surface 17 coincide with the information (H1 and H2) of the position and the shape of the isomagnetic surface (ECR surface 17) input in the recipe. That is, the control computer 32 corrects the coil current values of the coils 11 to 13 output by the plurality of coil power supplies 14, 15, and 16 to reduce a difference between the position and the shape of the isomagnetic surface (ECR surface 17) input from the input device 31 and the position and the shape of the isomagnetic surface actually measured by the camera 42.

By correcting the coil currents in this way, an aircraft difference between a plurality of the plasma processing apparatuses 101 can be eliminated. That is, the same processing can be implemented in the same recipe in the plurality of plasma processing apparatuses 101.

### INDUSTRIAL APPLICABILITY

The invention is applicable to a plasma processing apparatus that processes a sample on a substrate such as a semiconductor wafer by etching.

### REFERENCE SIGNS LIST

1: microwave source
2: isolator
3: automatic matching device
4: rectangular waveguide
5: circular rectangle converter
6: circular waveguide
7: hollow portion
8: microwave introduction window
9: shower plate
10: plasma processing chamber
11: upper portion coil
12: middle portion coil
13: lower portion coil
14: upper portion coil power supply
15: middle portion coil power supply
16: lower portion coil power supply
17: ECR surface
18: yoke
19: inner cylinder
20: gas supply hole
21: conductance adjustment valve
22: turbo molecular pump
23: processing target substrate
24: substrate stage and radio frequency electrode (sample stage)
25: insulating plate
26: bias power supply
27: automatic matching device
28: ground electrode
29: susceptor
30: stage cover
31: graphical user interface (input device)
32: control computer (control device)
38: recipe input screen
39: recipe
40: ECR surface shape screen
41: forbidden area of ECR surface
42: camera

1. A plasma processing apparatus comprising:
a processing chamber configured to allow a sample to be plasma-processed;
a radio frequency power supply configured to supply radio frequency power of a microwave for generating plasma;
a plurality of coils configured to form a magnetic field in the processing chamber;
a coil power supply configured to cause a current to flow through each of the coils;
a sample stage configured to allow the sample to be placed; and
a control device configured to control the coil power supply, wherein
the control device
receives information on a shape of an isomagnetic surface having a magnetic flux density for causing cyclotron resonance of a charged particle by interaction with the microwave,
obtains combinations of current values for forming the received shape of the isomagnetic surface based on a correlation between values of the currents and the shape of the isomagnetic surface,
obtains one desired combination of current values from the obtained combinations of current values based on a coil current selection reference, and
controls the coil power supply to cause each current in the obtained desired combination of current values to flow.

2. The plasma processing apparatus according to claim 1, wherein
an input range in the received information on the shape of the isomagnetic surface is limited based on a predetermined reference.

3. The plasma processing apparatus according to claim 1, wherein
the received information on the shape of the isomagnetic surface includes distances between the isomagnetic surface and the sample at a plurality of positions in a radial direction of the processing chamber.

4. The plasma processing apparatus according to claim 1, wherein
the control device corrects the values of the currents to reduce a difference between a shape of the isomagnetic surface actually measured by a measurement device and the received shape of the isomagnetic surface.

5. The plasma processing apparatus according to claim 1, wherein
the coil current selection reference is a reference created based on currents at which power consumption of the coil power supply is minimized and the received shape of the isomagnetic surface.

6. The plasma processing apparatus according to claim 1, wherein
the coil current selection reference is a reference created based on currents at which a gradient of a magnetic field on a central axis of the processing chamber is maximized and the received shape of the isomagnetic surface.

7. A plasma processing method using a plasma processing apparatus including a processing chamber configured to allow a sample to be plasma-processed, a radio frequency power supply configured to supply radio frequency power of microwave for generating plasma, a plurality of coils configured to form a magnetic field in the processing chamber, a coil power supply configured to cause a current to flow through each of the coils, and a sample stage configured to allow the sample to be placed, the plasma processing method comprising:
a step of receiving information on a shape of an isomagnetic surface having a magnetic flux density for causing cyclotron resonance of a charged particle by interaction with the microwave;
a step of obtaining combinations of current values for forming the received shape of the isomagnetic surface based on a correlation between values of the currents and the shape of the isomagnetic surface;
a step of obtaining one desired combination of current values from the obtained combinations of current values based on a coil current selection reference; and
a step of controlling the coil power supply to cause each current in the obtained desired combination of current values to flow.
